(19) United States
(12) Patent Application Publication
(10) Pub. No.: US 2016/0104669 A1
(43) Pub. Date: Apr. 14, 2016

(54) SEMICONDUCTOR STRUCTURE WITH IMPROVED METALLIZATION ADHESION AND METHOD FOR MANUFACTURING THE SAME

(71) Applicant: Infineon Technologies AG, Neubiberg (DE)

(72) Inventor: Alim Karmous, Villach (AT)

(21) Appl. No.: 14/509,079

(22) Filed: Oct. 8, 2014

(51) Int. Cl. H01L 23/528; H01L 23/532

(52) U.S. Cl. CPC H01L 23/528; H01L 23/53266

(57) ABSTRACT

A semiconductor structure is disclosed. The semiconductor structure may include a substrate, a first layer formed on a first side of the substrate and second layer formed over the first layer. The second layer may include a plurality of substantially pointed structures which interpenetrate through the first layer and extend into the substrate. A method for manufacturing a semiconductor structure is likewise disclosed.

### TECHNICAL FIELD

Various embodiments relate to a semiconductor structure with superior metallization adhesion compared to currently available technology and a method for manufacturing a semiconductor structure with superior metallization adhesion.

### BACKGROUND

Many semiconductor devices are constructed using a multi-layer stack structure wherein a metal or metallic material is adhered to a semiconductor material, silicon based power MOSFETs, for example. In the current technologies used to bond titanium to silicon, many current automated production techniques, e.g. mechanical sawing and vacuumed assisted chip pick up, may cause the backside metallization to “peel” off the semiconductor material. A currently available solution to prevent backside metallization peel off in silicon-titanium devices is to replace the titanium with another metal, such as an aluminum-copper-silicon composition. However, for many applications this solution may result in reduced device performance.

### SUMMARY

In various embodiments, a semiconductor structure is provided. The semiconductor structure may include a substrate with a first layer formed on a first side of the substrate and a second layer formed over the first layer. In various embodiments, the second layer may include a plurality of substantially pointed structures which interpenetrate through the first layer and extend into the substrate.

### BRIEF DESCRIPTION OF THE DRAWINGS

In the drawings, like reference characters generally refer to the same parts of the disclosure throughout the different views. The drawings are not necessarily to scale, emphasis instead generally being placed upon illustrating the principles of the disclosure. In the following description, various embodiments of the disclosure are described with reference to the following drawings, in which:

FIG. 1 shows, in accordance with a potential embodiment, a cross-sectional representation of a semiconductor structure including a first conductive layer formed on a substrate and a second conductive layer formed over the first conductive layer;

FIG. 2A shows, according to an embodiment, a cross-sectional representation of a semiconductor structure including a first conductive layer formed on a substrate and recesses formed through the first conductive layer and into the substrate;

FIG. 2B shows a cross-sectional representation of the semiconductor structure from FIG. 2A, where a second conductive layer has been formed over the first conductive layer;

FIGS. 3A and 3B show, experimental results obtained by construing a potential embodiment of a semiconductor structure;

FIGS. 4A & 4B depict, in flowchart form, a method of forming a semiconductor structure in accordance with various embodiments;

FIGS. 5A & 5B depict, in flowchart form, an additional method of forming a semiconductor structure in accordance with various embodiments;

### DESCRIPTION

The following detailed description refers to the accompanying drawings that show, by way of illustration, specific details and embodiments in which the disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface may be used herein to mean that the deposited material may be formed “directly on”, e.g. in direct contact with the implied side or surface. The word “over” used with regards to a deposited material formed “over” a side or surface may be used herein to mean that the deposited material may be formed “indirectly on” the implied side or surface with one or more additional layers being arranged between the implied side or surface and the deposited material.

The term “carrier structure” as used herein should be understood to include various structures such as, e.g. a lead frame, a semiconductor substrate, such as a silicon substrate, a printed circuit board, and/or various flexible substrates.

In various embodiments, a semiconductor device with improved backside metallization adhesion characteristics that can withstand modern automated manufacturing techniques is provided.

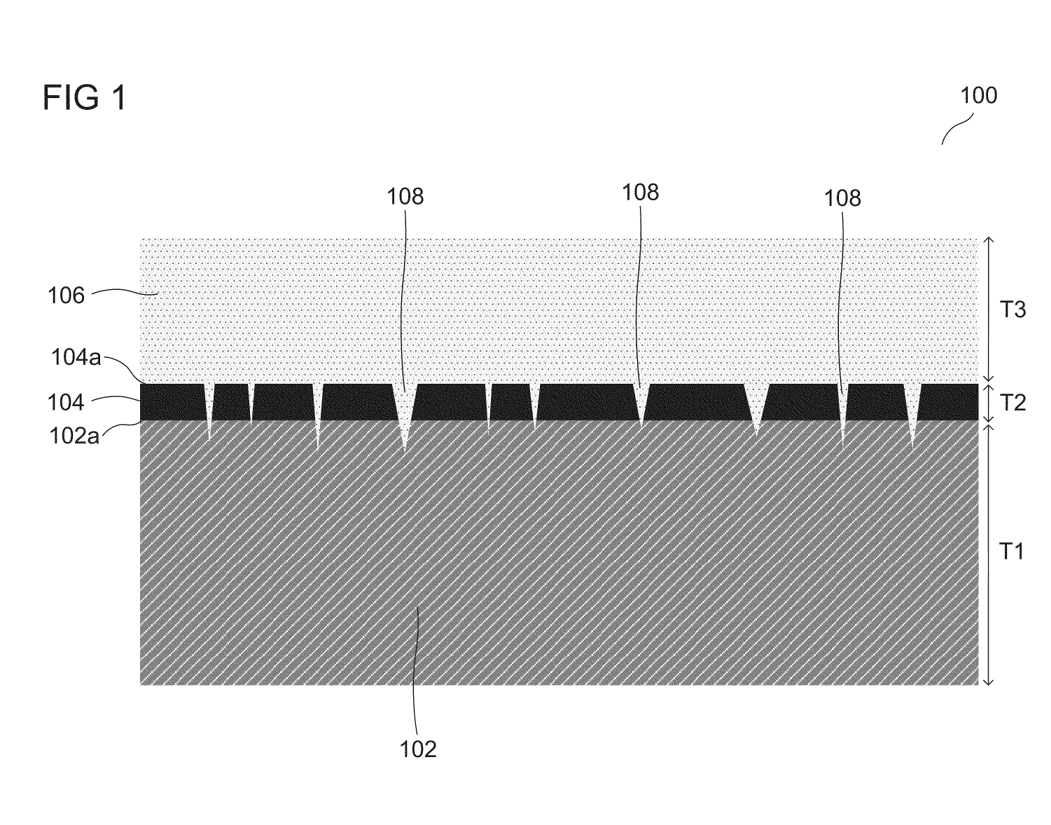

According to various embodiments, as illustrated in FIG. 1, a semiconductor structure 100 is disclosed. The semiconductor structure 100 may include a substrate 102, a first conductive layer 104, which may be formed on and/or over a first side 102a of the substrate 102. In various embodiments, the semiconductor structure 100 may further include a second conductive layer 106 formed on and/or over the first conductive layer 104. The second conductive layer 106 may include or essentially consist of a plurality of substantially pointed structures 108 which interpenetrate through the first conductive layer 104 (in other words extend through the first conductive layer 104) and further extend into the substrate 102. According to various embodiments, the semiconductor structure 100, though generally described herein with regard to a diode, may be implemented in a wide array of semiconductor devices, e.g. devices where titanium is coupled and/or or adhered to n-doped silicon, e.g. a silicon based power MOSFET, such as an Infineon Technologies CoolMOS™. In some embodiments, the semiconductor structure 100 may be implemented without the use of the substrate 102. According to various embodiments, the semiconductor structure 100 may be fabricated with another material serving as a surrogate for the substrate 102 and depositing the completed structure onto the substrate 102. According to an embodiment, the semiconductor structure 100 may be implemented as a stacked-layer structure in which the substrate 102 may be a silicon and/or silicon-based layer. In at least one embodiment, the semiconductor structure 100 may be implemented as a stacked-layer structure in which the first conductive layer 104 may be a titanium and/or titanium-based layer. According to an embodiment, the semiconductor structure 100 may be implemented as a stacked-layer structure in which the second conductive layer 106 may be implemented as an aluminum and/or aluminum-based layer. According to an embodiment, the semiconductor structure 100 may be implemented as a stacked-layer structure in which the substrate 102 may be a silicon dioxide based layer, the first conductive layer 104 may be a titanium tungsten based layer, and the second conductive layer 106 may be an aluminum based layer. According to an embodiment, the semiconductor structure 100 may be implemented as a stacked-layer structure in which the substrate 102 may be a silicon dioxide based layer, the first conductive layer 104 may be a titanium nitride based layer, and the second conductive layer 106 may be an aluminum based layer. According to an embodiment, the semiconductor structure 100 may be implemented as a stacked-layer structure in which the substrate 102 may be a copper based layer, the first conductive layer 104 may be a non-conductive aluminum oxide based layer, and the second conductive layer 106 may be a non-conductive silicon nitride based layer. According to various exemplary embodiments, the semiconductor structure 100 may be implemented as a stacked-layer structure where the plurality of substantially pointed structures 108 may be employed to improve an adhesion between non-conductive layers. In various embodiments, the substrate 102 may include or essentially consist of a semiconductor material such as germanium, silicon germanium, silicon carbide, gallium nitride, indium, indium gallium nitride, indium gallium arsenide, indium gallium zinc oxide, or other elemental and/or compound semiconductors, e.g. a III-V compound semiconductor such as e.g. gallium arsenide or indium phosphide, or a II-VI compound semiconductor or a ternary compound semiconductor or a quaternary compound semiconductor, as may be desired for a given application. The substrate 102 may include or essentially consist of, for example, glass, and/or various polymers. The substrate 102 may be a silicon-on-insulator (SOI) structure. In some embodiments the substrate 102 may be a printed circuit board. According to various embodiments, the substrate 102 may be a flexible substrate, such as a flexible plastic substrate, e.g. a polyimide substrate. In various embodiments, the substrate 102 may be composed of or may include one or more of the following materials: a polyester film, a thermoset plastic, a metal, a metalized plastic, a metal foil, and a polymer. In various embodiments, the substrate 102 may be a flexible laminate structure. According to various embodiments, the substrate 102 may be a semiconductor substrate, such as a silicon substrate. In some embodiments, the substrate 102 may be a multilayer substrate, e.g. a multilayer polymer, multilayer glass-ceramic, multilayer glass-ceramic copper, etc. The substrate 102 may include or essentially consist of other materials or combinations of material, for example various dielectrics, metals, and polymers as may be desirable for a given application. In various embodiments, the substrate 102 may have a thickness T1 in the range from about 100 μm to about 700 μm, e.g. in the range from about 150 μm to about 650 μm, e.g. in the range from about 200 μm to about 600 μm, e.g. in the range from about 250 μm to about 550 μm, e.g. in the range from about 300 μm to about 500 μm, e.g. in the range from about 350 μm to about 450 μm. In some embodiments, the substrate 102 may have a thickness T1 of at least about 100 μm, e.g. of at least 150 μm, e.g. of at least 200 μm, e.g. of at least 250 μm, e.g. of at least 300 μm. In various embodiments, the substrate 102 may have a thickness T1 of less than or equal to about 700 μm, e.g. of less than or equal to 650 μm, e.g. of less than or equal to 600 μm, e.g. of less than or equal to 550 μm, e.g. of less than or equal to 500 μm. According to various embodiments, the substrate 102 may have a thickness T1 which may be any thickness desirable for a given application. In various embodiments, the substrate 102 may be square or substantially square in shape. The substrate 102 may be rectangular or substantially rectangular in shape. According to various embodiments, the substrate 102 may be a circle or substantially circular in shape. The substrate 102 may be an oval or substantially oval-like in shape. According to various embodiments, the substrate 102 may be a triangle or substantially triangular in shape. The substrate 102 may be a cross or substantially cross shaped. According to various embodiments, the substrate 102 may be formed into any shape that may be desired for a given application.

In various embodiments, first conductive layer 104 may be formed of a conductive material such as a metallic material, a metalized material, a metal foil, an elemental metal, and/or a metal alloy. For example, the first conductive layer 104 may include or essentially consist of copper, nickel, tin, lead, silver, gold, aluminum, titanium, gallium, indium, boron, and various alloys of these metals such as e.g. cupronickel, nickel-aluminum, aluminum-copper-silicon, etc. In some embodiments, the first conductive layer 104 may be a multilayer substrate, e.g. a multilayer polymer, multilayer glass-ceramic, multilayer glass-ceramic copper, etc. Further, the first conductive layer 104 may include or essentially consist of other materials as may be desirable for a given application. According to various embodiments, the first conductive layer 104 may have a thickness, T2, in the range from about 20 nm to about 500 nm, e.g. in the range from about 20 nm to about 30 nm, e.g. in the range from about 30 nm to about 40 nm, e.g. in the range from about 40 nm to about 50 nm, e.g. in the range from about 50 nm to about 100 nm, e.g. in the range from about 100 nm to about 150 nm, e.g. in the range from about 150 nm to about 200 nm, e.g. in the range from about 200 nm to about 250 nm, e.g. in the range from about 250 nm to about 300 nm, e.g. in the range from about 300 nm to about 350 nm, e.g. in the range from about 350 nm to about 500 nm. According to various embodiments, the first conductive layer 104 may be deposited through various techniques, e.g. vapor deposition, an electrochemical process, and electroplating process, an electroless process, a chemical vapor deposition process, molecular beam epitaxy, spin coating, a sputter deposition, and/or various other techniques as may be desirable for a given application. In various embodiments, the first conductive layer 104 may be square or substantially square in shape. The first conductive layer 104 may be rectangular or substantially rectangular in shape. According to various embodiments, the first conductive layer 104 may be a circle or substantially circular in shape. The first conductive layer 104 may be an oval or substantially oval-like in shape. According to various embodiments, the first conductive layer 104 may be a triangle or substantially triangular in shape. The first conductive layer 104 may be a cross or substantially cross shaped. According to various embodiments, the first conductive layer 104 may be formed into any shape that may be desired for a given application.

According to various embodiments, the second conductive layer 106 may have a thickness, T3, in the range from about 100 nm to about 5 μm, e.g. in the range from about 100 nm to about 200 nm, e.g. in the range from about 200 nm to about 300 nm, e.g. in the range from about 300 nm to about 500 nm, e.g. in the range from about 500 nm to about 1 μm, e.g. in the range from about 1 μm to about 5 μm. In some embodiments, the second conductive layer 106 may have a thickness T3 of at least about 100 nm, e.g. of at least 150 nm, e.g. of at least 200 nm, e.g. of at least 250 nm, e.g. of at least 300 nm. In at least one embodiment, the second conductive layer 106 may have a thickness T3 of less than or equal to about 2 μm, e.g. of less than or equal to 1.6 μm, e.g. of less than or equal to 1 μm, e.g. of less than or equal to 550 nm, e.g. of less than or equal to 500 nm. In various embodiments, the second conductive layer 106 may be square or substantially square in shape. The second conductive layer 106 may be rectangular or substantially rectangular in shape. According to various embodiments, the second conductive layer 106 may be a circle or substantially circular in shape. The second conductive layer 106 may be an oval or substantially oval-like in shape. According to various embodiments, the second conductive layer 106 may be a triangle or substantially triangular in shape. The second conductive layer 106 may be a cross or substantially cross shaped. According to various embodiments, the second conductive layer 106 may be formed into any shape that may be desired for a given application. The second conductive layer 106 may include or essentially consist of a conductive material, e.g. a metallic material, a metalized material, a metal foil, an elemental metal, and/or a metal alloy. For example, the second conductive layer 106 may include or essentially consist of copper, nickel, tin, lead, silver, gold, aluminum, titanium, gallium, indium, boron, and various alloys of these metals such as e.g. cupronickel, nickel-aluminum, aluminum-copper-silicon, etc. Further, the second conductive layer 106 may include or essentially consist of other materials as may be desirable for a given application. According to various embodiments, the second conductive layer 106 may be deposited through various techniques, e.g. vapor deposition, an electrochemical process, and electroplating process, an electroless process, a chemical vapor deposition process, molecular beam epitaxy, a lithography process, spin coating, a sputter deposition, and/or various other techniques as may be desirable for a given application. In various embodiments, the second conductive layer 106 may further include a plurality of spike-like structures 108.

The spike-like structures 108 may at least partially permeate the first conductive layer 104. In other words, the spike-like structures 108 may extend from the second conductive layer 106 and partially penetrate the first conductive layer 104. The spike-like structures 108 may extend into and/or through a surface 104a of the first conductive layer 104. The surface 104a may be a top surface of the first conductive layer 104. Said another way, the surface 104a may be the surface of the first conductive layer 104 over which the second conductive layer 106 may be formed. According to various embodiments, the spike like structures 108 may completely penetrate through the first conductive layer 104 and extend into the substrate 102. In various embodiments, the spike-like structures 108 may be conical and/or essentially conical in shape, with the apex of the conical shape situated in the first conductive layer 104. According to an embodiment, the spike like structures 108 may be domed or be essentially dome-like in shape. The spike-like structures 108 may be pyramidal or essentially pyramid-like in shape. The spike-like structures 108 may all have essentially the same shape in some embodiments, while in other embodiments the spike-like structures 108 may be irregularly shaped. In various embodiments, the surface area of the top surface 104a of the first conductive layer 104 occupied by the entire plurality of spike-like structures 108 may be less than 10 percent, e.g. in the range from about 10 percent to about 8 percent, e.g. in the range from about 8 percent to about 6 percent, e.g. in the range from about 6 percent to about 4 percent, e.g. in the range from about 4 percent to about 2 percent, e.g. in the range from about 2 percent to less than 1 percent. The spike-like structures 108 may be formed through the use of an annealing process. For example, an annealing process which causes portions of the second conductive layer 106 to expand and/or morph into the spike like structures 108.

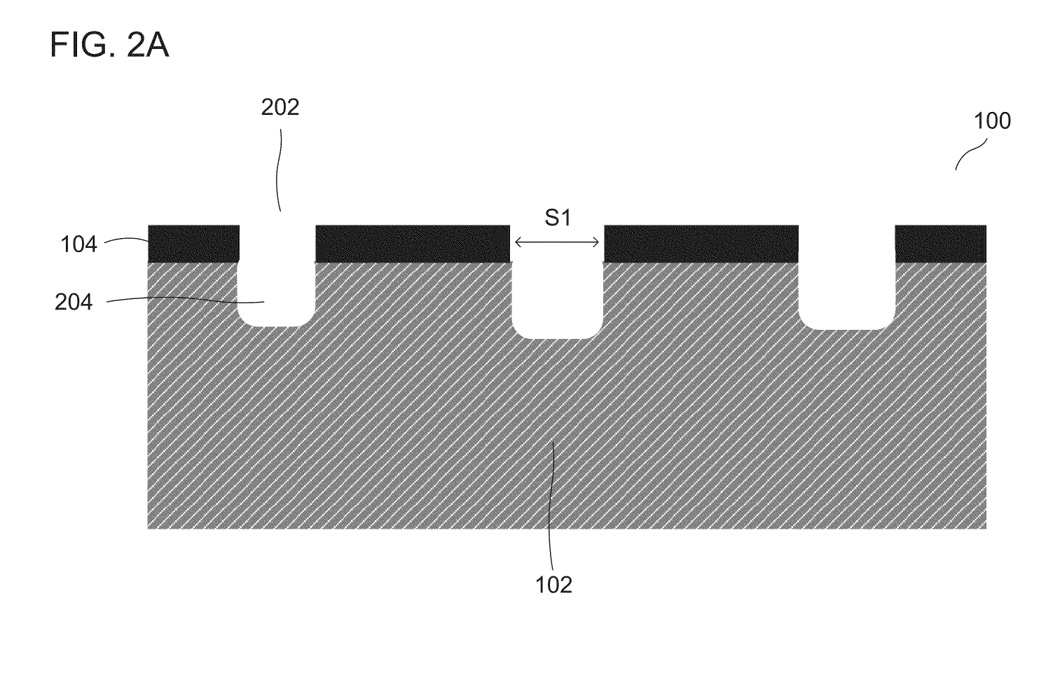

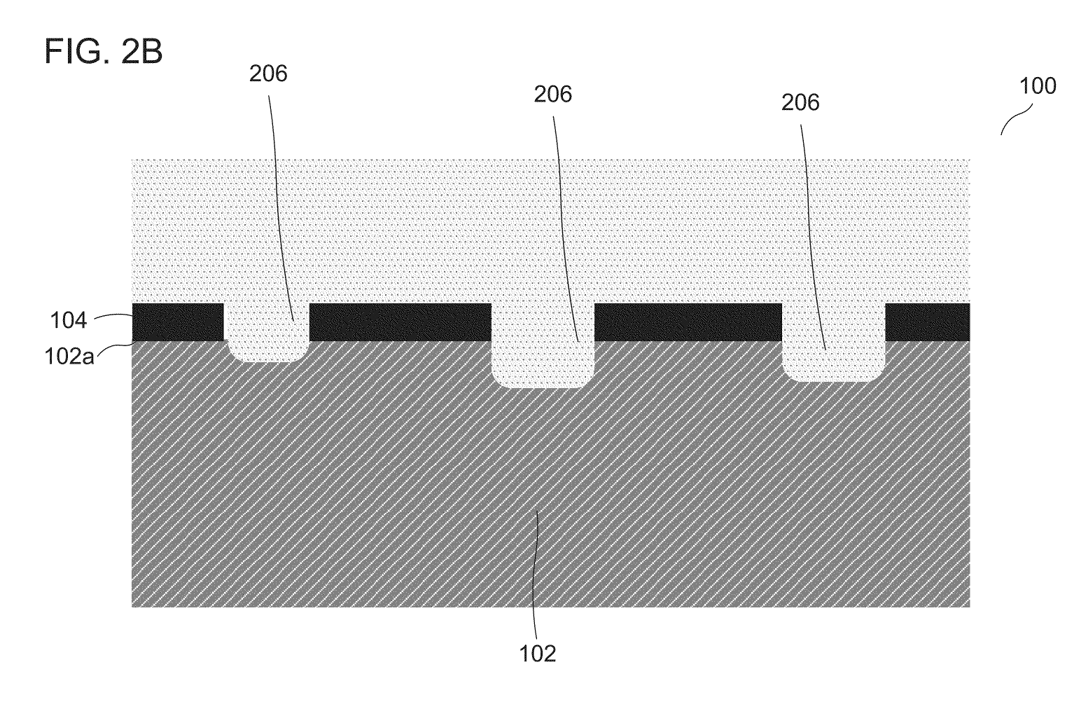

According to an embodiment, as illustrated in FIGS. 2A and 2B, the semiconductor structure 100 may include a plurality of perforations 202 in the first conductive layer 104 and a plurality of recesses 204 formed in the substrate 102 and coaxially located with the plurality of perforations 202. In various embodiments, the second conductive layer 106 may include a plurality of post-like structures 206. The post-like structures 206 may each extend through a single perforation 202 from said plurality formed in the first conductive layer 104 and may be coupled to a surface of a recess 204 from said plurality formed in the substrate 102.

According to various embodiments, the plurality of perforations 202 may be formed in through first conductive layer 104 using various techniques, e.g. laser drilling, various grinding techniques, deep reactive-ion etching, isotropic gas phase etching, vapor etching, wet etching, isotropic dry etching, plasma etching, various lithography techniques, etc. In various embodiments, each perforation 202 may be square or substantially square in shape. Each perforation 202 may be rectangular or substantially rectangular in shape. According to various embodiments, each perforation 202 may be a circle or substantially circular in shape. Each perforation 202 may be an oval or substantially oval-like in shape. According to various embodiments, each perforation 202 may be a triangle or substantially triangular in shape. Each perforation 202 may be a cross or substantially cross shaped. According to various embodiments, each perforation 202 may be formed into any shape that may be desired for a given application. In at least one embodiment, the distance, represented by reference numeral Si, across each perforation 202, may be in the range from about 0.5 μm to about 3.0 μm; e.g. in the range from about 0.5 μm to about 0.75 μm; e.g. in the range from about 0.75 μm to about 1.0 μm; e.g. in the range from about 1.0 μm to about 1.25 μm; e.g. in the range from about 1.25 μm to about 1.50 μm; e.g. in the range from about 1.50 μm to about 1.75 μm; e.g. in the range from about 1.75 μm to about 2.0 μm; e.g. in the range from about 2.0 μm to about 2.25 μm; e.g. in the range from about 2.25 μm to about 2.50 μm; e.g. in the range from about 2.50 μm to about 2.75 μm; e.g. in the range from about 2.75 μm to about 3.0 μm.

According to various embodiments, the plurality of recesses 204 may be formed in the substrate 102 using various techniques, e.g. laser drilling, various grinding techniques, deep reactive-ion etching, isotropic gas phase etching, vapor etching, wet etching, isotropic dry etching, plasma etching, various lithography techniques, etc. In various embodiments, each recess 204 may be square or substantially square in shape. Each recess 204 may be rectangular or substantially rectangular in shape. According to various embodiments, each recess 204 may be a circle or substantially circular in shape. Each recess 204 may be an oval or substantially oval-like in shape. According to various embodiments, each recess 204 may be a triangle or substantially triangular in shape. Each recess 204 may be a cross or substantially cross shaped. According to various embodiments, each recess 204 may be formed into any shape that may be desired for a given application. In some embodiments, the plurality of recesses may not be necessary and/or may be excluded entirely from the semiconductor structure 100.

According to an embodiment, as illustrated in FIG. 2B, the semiconductor structure 100 may include a plurality of post-like structures 206. The post-like structures 206 may each extend through a single perforation 202 from said plurality formed in the first conductive layer 104 and may be coupled to a surface of a recess 204 from said plurality formed in the substrate 102. In some embodiments, the post-like structures 206 may be integrally formed with the second conductive layer 106. For example, the second conductive layer 106 and the plurality of post-like structures 206 may be composed of or may include the same material, such as copper, nickel, tin, lead, silver, gold, aluminum, titanium, gallium, indium, boron, and various alloys of these metals such as e.g. cupronickel, nickel-aluminum, aluminum-copper-silicon, etc. According to various embodiments, the second conductive layer 106 and the plurality of post-like structures 206 may be deposited and/or formed together in one step through various techniques, e.g. vapor deposition, an electrochemical process, an electroplating process, an electroless process, a chemical vapor deposition process, molecular beam epitaxy, a lithography process, spin coating, a sputter deposition, and/or various other techniques as may be desirable for a given application. In some embodiments, each of the post-like structures 206 may be in physical and/or electrical contact with a surface of a single perforation 202 from said plurality formed in the first conductive layer 104. Further, each of the post-like structures 206 may be in physical and/or electrical contact and/or coupled to a surface of a recess 204 from said plurality formed in the substrate 102. In at least one embodiment, the plurality of post-like structures 206 may be electrically coupled to the first conductive layer 104 and electrically insulated and/or isolated from the substrate 102. According to an embodiment, the plurality of post-like structures 206 may be coupled and/or fixed to substrate 102 by various annealing processes, e.g. by annealing the transducer structure 100 at temperatures in the range from about 300 degrees Celsius to about 500 degrees Celsius; e.g. in the range from about 300° C. to about 350° C.; e.g. from about 350° C. to about 400° C.; e.g. from about 400° C. to about 450° C.; e.g. from about 450° C. to about 500° C. Further, the annealing process may be from about 30 minutes in duration to about 240 minutes; e.g. from about 30 minutes to about 60 minutes; e.g. from about 60 minutes to about 90 minutes; e.g. from about 90 minutes to about 120 minutes; e.g. from about 120 minutes to about 150 minutes; e.g. from about 150 minutes to about 180 minutes; e.g. from about 180 minutes to about 210 minutes; e.g. from about 210 minutes to about 240 minutes. According to various embodiments where the transducer structure 100 may be implemented without the plurality of recesses 204, each of the post-like structures 206 may be coupled to the substrate 102 and/or the first conductive layer 104 through an annealing process similar to the processes described above. Further, in such embodiments, the annealing process may cause portions of the post-like structures 206 to protrude into and/or penetrate the top surface 102a of the substrate 102.

According to various embodiments, the first conductive layer 104 may be implemented as a permeable bather layer. For example, a titanium layer which is sufficiently thin so that during an annealing process it becomes permeable to aluminum and/or silicon grains which may grow and/or be formed during the annealing. In an exemplary embodiment, the first conductive layer 104 may be implemented as a thin, permeable titanium bather layer. In an embodiment, this thin titanium bather layer may replace the titanium backside contact in a semiconductor diode. According to various embodiments, replacing the conventional titanium backside diode contact with a thinner, more permeable titanium layer may improve the adhesion of the backside metallization titanium to the silicon in the diode. In various embodiments, an aluminum based metal layer may be deposited over the permeable titanium layer and the diode may be subjected to various annealing processes similar to those described above. The annealing may cause various protrusions, growths, and/or spikes to form on the aluminum based metal layer. Many of these aluminum based spikes and/or protrusions may extend through the permeable titanium layer and penetrate into the silicon layer. This “spiking” may cause an increased and/or more robust adhesion between the titanium layer and the silicon in the diode. Various properties of the aluminum based spikes, e.g. length, thickness, extent of penetration into the silicon layer, etc., may be tailored and/or adjusted by altering the thickness of the permeable titanium layer. According to some embodiments, characteristics of the aluminum based spikes may be adjusted by changing the composition of aluminum based metal layer deposited over the permeable titanium layer. Further, in at least on embodiment, characteristics of the aluminum based spikes may be adjusted by regulating the so-called thermal budget of the annealing process. Additionally, in various embodiments, the characteristics of the aluminum based spikes may be adjusted so that the backside diode contact surface area occupied by the aluminum based spikes may only be a minor fraction of the total surface area of the backside diode contact.

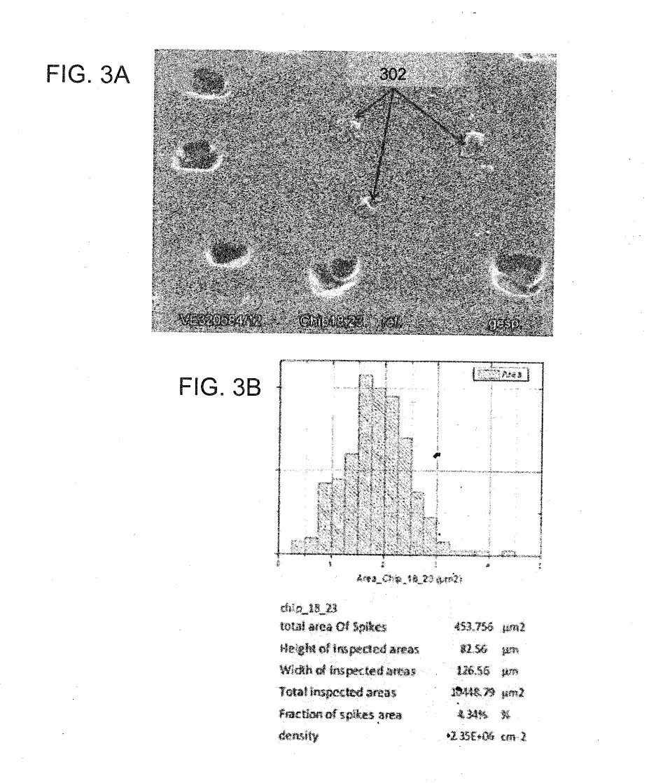

FIGS. 3A and 3B show various embodiments of the semiconductor structure 100 implemented in a semiconductor diode and some empirical measurements displaying the “spiking” described above. FIG. 3A depicts the backside surface of a diode after the backside metal stack has been removed. The metal stack depicted in FIG. 3A contained the following layers formed over a silicone substrate: a 500 nm aluminum-copper-silicon layer, a 200 nm titanium layer, and 2000 nm aluminum-copper-silicon layer. The metal stack was then annealed at 400° C. for 120 min. As represented in FIG. 3B, the “spikes” as described above were measured to occupy less than 5% of the surface of the diode backside. If the “spiking” shown in FIG. 3B was implemented in a diode with a titanium contact, the effect on the operation of diode is a minor degradation of the contact resistance, e.g. 5% reduction of titanium to silicon contact area while simultaneously providing aluminum based spikes at the aluminum-copper-silicon to silicon interface occupying an area greater than 5% of the total planar contact area due to the lateral surface of the spikes. In some embodiments, these spikes may increase the adhesion between the titanium and silicon layers respectively without decreasing the performance of the diode, e.g. an increase in the forward voltage generally associated by using aluminum-copper-silicon in diode production. The increase forward voltage in diodes that utilize an aluminum-based backside contact may be caused by a higher contact resistance between n-doped silicon and the aluminum alloy as compared to titanium. As shown in FIG. 3A, the increase in forward voltage may also be partially attributed to the growth of silicon grains 302 during annealing at the aluminum-copper-silicon to silicon interface because the silicon grains 302 tend to be p-doped as they grow from the aluminum-copper-silicon layer. These p-doped silicon grains 302 increase the contact resistance between the aluminum-copper-silicon layer and the n-doped silicon. However, according to various embodiments where the semiconductor structure 100 may have an aluminum-copper-silicon layer formed over a permeable titanium layer, the p-doped silicon grains 302 would grow at that interface and therefore may have no effect on the contact resistance.

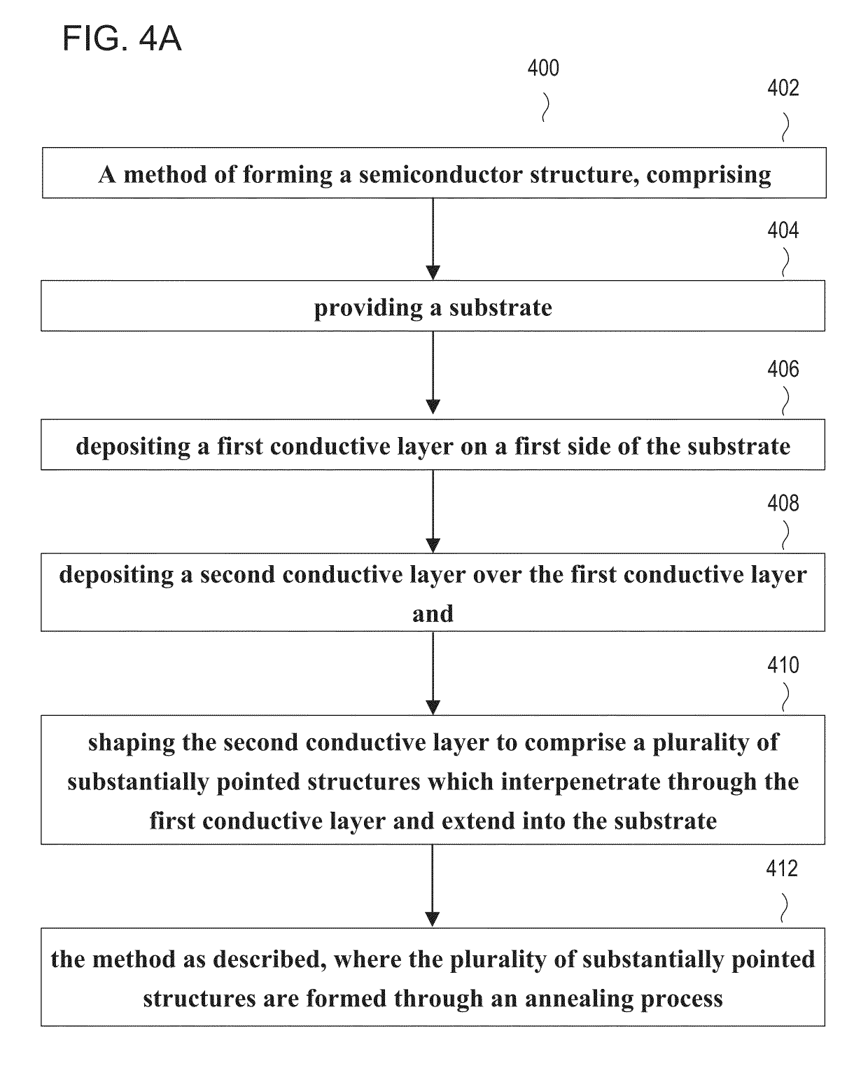

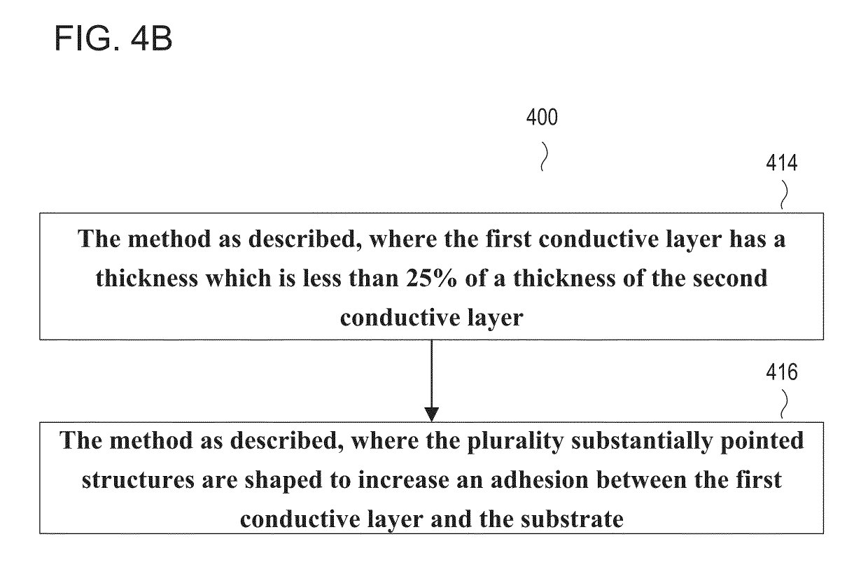

According to various embodiments, as illustrated in FIGS. 4A and 4B, a method, identified by reference numeral 400, of forming a semiconductor structure is disclosed. As indicated by reference numeral 402, the method of forming a semiconductor structure 400 may include the following steps. In some embodiments and identified as 404, the method 400 may include providing a substrate. In some embodiments and identified as 406, the method 400 may include depositing a first conductive layer on a first side of the substrate provided. In some embodiments and identified as 408, the method 400 may include depositing a second conductive layer over the first conductive layer. In some embodiments and identified as 410, the method 400 may include shaping the second conductive layer to comprise a plurality of substantially pointed structures which interpenetrate through the first conductive layer and extend into the substrate. In some embodiments and identified as 412, the method 400 may include forming the plurality of substantially pointed structures through an annealing process. In some embodiments and identified as 414, the method 400 may include an embodiment where the first conductive layer may have a thickness which is less than 25% of a thickness of the second conductive layer. In some embodiments and identified as 416, the method 400 may include an embodiment where the plurality substantially pointed structures may be shaped to increase an adhesion between the first conductive layer and the substrate. In at least one embodiment, the method 400 may be used to form the semiconductor structure 100, as described above.

The substrate provided in method 400 may include or essentially consist of a semiconductor material such as germanium, silicon germanium, silicon carbide, gallium nitride, indium, indium gallium nitride, indium gallium arsenide, indium gallium zinc oxide, or other elemental and/or compound semiconductors, e.g. a III-V compound semiconductor such as e.g. gallium arsenide or indium phosphide, or a II-VI compound semiconductor or a ternary compound semiconductor or a quaternary compound semiconductor, as may be desired for a given application. The substrate of method 400 may include or may be composed of, for example, glass, and/or various polymers. The substrate of method 400 may be a silicon-on-insulator (SOI) structure. In some embodiments the substrate of method 400 may be a printed circuit board. According to various embodiments, the substrate of method 400 may be a flexible substrate, such as a flexible plastic substrate, e.g. a polyimide substrate. In various embodiments, the substrate of method 400 may be composed of or may include one or more of the following materials: a polyester film, a thermoset plastic, a metal, a metalized plastic, a metal foil, and a polymer. In various embodiments, the substrate of method 400 may be a flexible laminate structure. According to various embodiments, the substrate of method 400 may be a semiconductor substrate, such as a silicon substrate. The substrate of method 400 may include or essentially consist of other materials or combinations of material, for example various dielectrics, metals, and polymers as may be desirable for a given application.

The first conductive layer of the method 400 may be formed of a metallic material, a metalized material, a metal foil, an elemental metal, and/or a metal alloy. For example, the first conductive layer of the method 400 may be composed of or may include copper, nickel, tin, lead, silver, gold, aluminum, titanium, gallium, indium, boron, and various alloys of these metals such as e.g. cupronickel, nickel-aluminum, aluminum-copper-silicon, etc. Further, the first conductive layer of method 400 may include or may be composed of other materials as may be desirable for a given application.

The second conductive layer of the method 400 may be composed of or may include any of the materials listed above for the first conductive layer of the method 400.

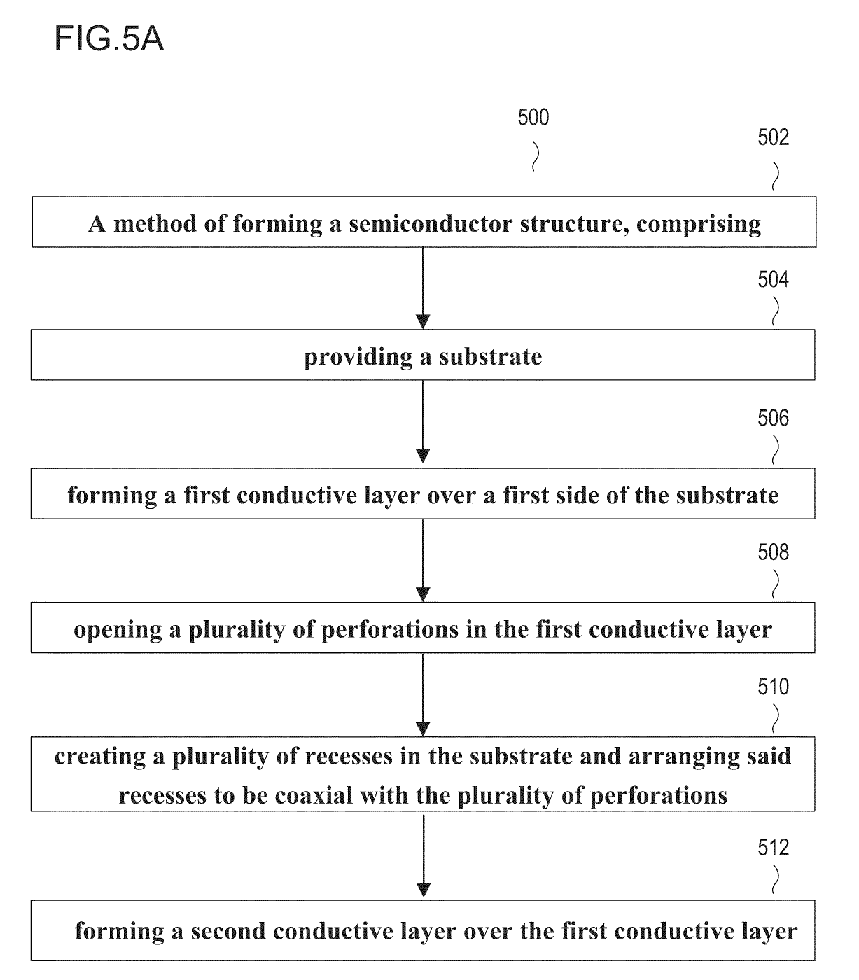

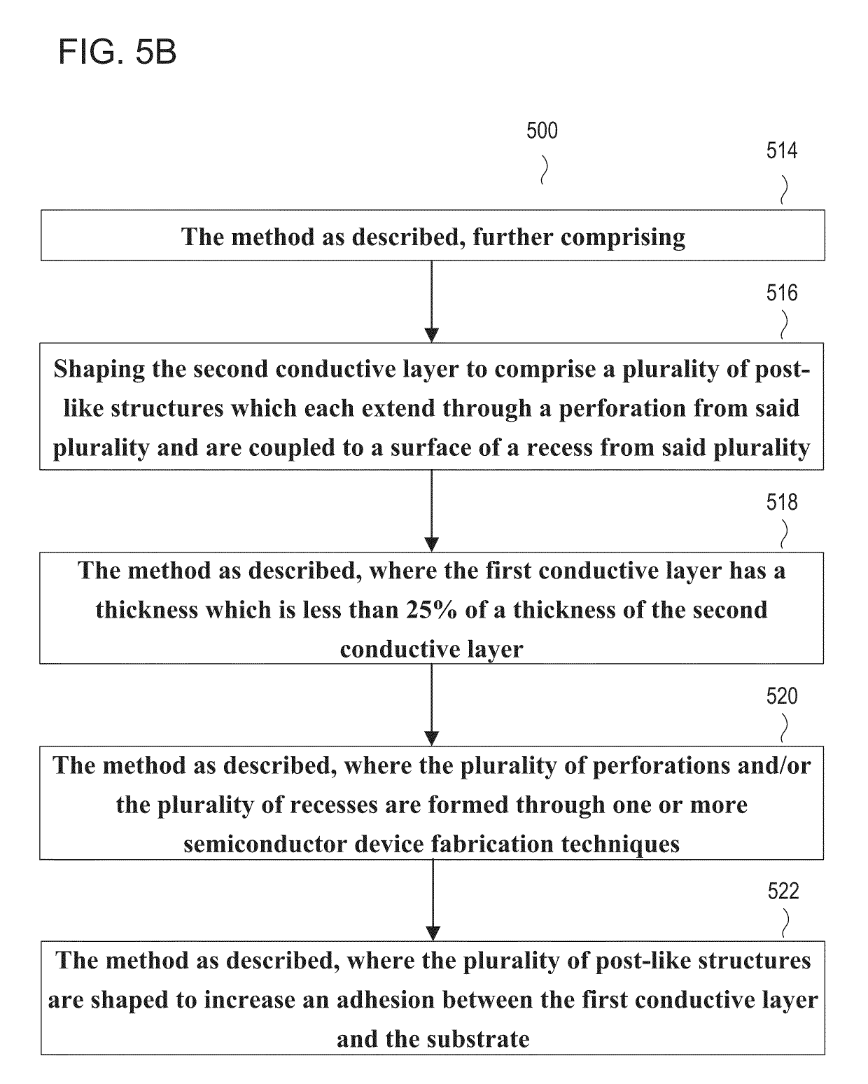

According to various embodiments, as illustrated in FIGS. 5A and 5B, a method, identified by reference numeral 500, of forming a semiconductor structure is disclosed. As indicated by reference numeral 502, the method of forming a semiconductor structure 500 may include the following steps. In some embodiments and identified as 504, the method 500 may include providing a substrate. In some embodiments and identified as 506, the method 500 may include forming a first conductive layer over a first side of the substrate provided. In some embodiments and identified as 508, the method 500 may include opening a plurality of perforations in the first conductive layer. In some embodiments and identified as 510, the method 500 may include creating a plurality of recesses in the substrate and arranging the recesses to be coaxial with the plurality of perforations in the first conductive layer. In some embodiments and identified as 512, the method 400 may include forming a second conductive layer over the first conductive layer. In some embodiments and identified as 514, the method 500 may further include the following steps. In some embodiments and identified as 516, the method 500 may include shaping the second conductive layer to comprise a plurality of post-like structures which each extend through a perforation from said plurality and may be coupled to a surface of a recess from said plurality. In some embodiments and identified as 518, the method 500 may include an embodiment where the first conductive layer has a thickness which is less than 25% of a thickness of the second conductive layer. In some embodiments and identified as 520, the method 500 may include an embodiment where the plurality of perforations and/or the plurality of recesses are formed through one or more semiconductor device fabrication techniques. In some embodiments and identified as 522, the method 500 may include an embodiment where the plurality of post-like structures are shaped to increase an adhesion between the first conductive layer and the substrate. In at least one embodiment, the method 500 may be used to form the semiconductor structure 100, as described in detail above.

The following examples pertain to further embodiments.

In Example 1, a semiconductor structure, which may include a substrate; a first conductive layer formed on a first side of the substrate; and a second conductive layer formed over the first conductive layer; the second conductive layer may include a plurality of substantially pointed structures which may interpenetrate through the first conductive layer and extend into the substrate.

In Example 2, the semiconductor structure of Example 1, where the plurality of substantially pointed structures may increase an adhesion between the first conductive layer and the substrate.

In Example 3, the semiconductor structure of Example 1 or 2, where the first conductive layer may have a thickness which is less than 25% of a thickness of the second conductive layer.

In Example 4, the semiconductor structure of any one of Examples 1 to 3, where the first conductive layer may be implemented as a titanium layer.

In Example 5, the semiconductor structure of any one of Examples 1 to 4, where the second conductive layer may be implemented as an aluminum-based layer.

In Example 6, the semiconductor structure of any one of Examples 1 to 5, where the plurality of substantially pointed structures may occupy less than 10% of the surface area of a side of the first conductive layer which may be in contact with the first side of the substrate.

In Example 7, a semiconductor structure, which may include a substrate; a first conductive layer formed over a first side of the substrate; a second conductive layer formed over the first conductive layer; a plurality of perforations in the first conductive layer; and a plurality of recesses in the substrate arranged to be coaxial with the plurality of perforations; where the second conductive layer may include a plurality of post-like structures which each extend through a perforation from said plurality and may be coupled to a surface of a recess from said plurality.

In Example 8, the semiconductor structure of Example 7, where the plurality of post-like structures may increase an adhesion between the first conductive layer and the substrate.

In Example 9, the semiconductor structure of Example 7 or 8, where the first conductive layer may be implemented as a titanium layer.

In Example 10, the semiconductor structure of any one of Examples 7 to 9, where the second conductive layer may be implemented as an aluminum-based layer.

In Example 11, the semiconductor structure of any one of Examples 7 to 10, where the plurality of post-like structures may occupy less than 10% of the surface area of a side of the first conductive layer which may be in contact with the first side of the substrate.

In Example 12, a method of forming a semiconductor structure, which may include providing a substrate; depositing a first conductive layer on a first side of the substrate; depositing a second conductive layer over the first conductive layer; and shaping the second conductive layer to include a plurality of substantially pointed structures which may interpenetrate through the first conductive layer and extend into the substrate.

In Example 13, the method of Example 12, where the plurality of substantially pointed structures may be formed through an annealing process.

In Example 14, the method of Example 12 or 13, where the first conductive layer may have a thickness which is less than 25% of a thickness of the second conductive layer.

In Example 15, the method of any one of Examples 12 to 14, where the plurality substantially pointed structures may be shaped to increase an adhesion between the first conductive layer and the substrate.

In Example 16, a method of forming a semiconductor structure, which may include providing a substrate; forming a first conductive layer over a first side of the substrate; forming a second conductive layer over the first conductive layer; opening a plurality of perforations in the first conductive layer; and creating a plurality of recesses in the substrate and arranging said recesses to be coaxial with the plurality of perforations.

In Example 17, the method of Example 16 may further include shaping the second conductive layer to include a plurality of post-like structures which each extend through a perforation from said plurality and are coupled to a surface of a recess from said plurality.

In Example 18, the method of Example 16 or 17, where the first conductive layer may have a thickness which is less than 25% of a thickness of the second conductive layer.

In Example 19, the method of any one of Examples 16 to 18, where the plurality of perforations and/or the plurality of recesses may be formed through one or more semiconductor device fabrication techniques.

In Example 20, the method of any one of Examples 16 to 19, where the plurality post-like structures may be shaped to increase an adhesion between the first conductive layer and the substrate.

What is claimed is:

1. A semiconductor structure, comprising:
a substrate;
a first layer formed on a first side of the substrate; and
a second layer formed over the first layer;
the second layer comprising a plurality of substantially pointed structures which interpenetrate through the first layer and extend into the substrate.

2. The semiconductor structure of claim 1,
wherein the plurality of substantially pointed structures increases an adhesion between the first layer and the substrate.

3. The semiconductor structure of claim 1,
wherein the first layer has a thickness which is less than 25% of a thickness of the second layer.

4. The semiconductor structure of claim 1,
wherein the first layer comprises a titanium layer.

5. The semiconductor structure of claim 1,
wherein the second layer comprises an aluminum-based layer.

6. The semiconductor structure of claim 1,
wherein the plurality of substantially pointed structures occupy a fraction of the surface area of a side of the first layer which is in contact with the first side of the substrate.

7. A semiconductor structure, comprising:
a substrate;
a first conductive layer formed over a first side of the substrate;
a second conductive layer formed over the first conductive layer;
a plurality of perforations in the first conductive layer; and
a plurality of recesses in the substrate arranged to be coaxial with the plurality of perforations;
wherein the second conductive layer comprises a plurality of post-like structures which each extend through a perforation from said plurality and are coupled to a surface of a recess from said plurality.

8. The semiconductor structure of claim 7,
wherein the plurality of post-like structures increase an adhesion between the first conductive layer and the substrate.

9. The semiconductor structure of claim 7,
wherein the first conductive layer comprises a titanium layer.

10. The semiconductor structure of claim 7,
wherein the second conductive layer comprises an aluminum-based layer.

11. The semiconductor structure of claim 7,
wherein the plurality of post-like structures occupy less than 10% of the surface area of a side of the first conductive layer which is in contact with the first side of the substrate.

12. A method of forming a semiconductor structure, the method comprising:
providing a substrate;
depositing a first conductive layer on a first side of the substrate;
depositing a second conductive layer over the first conductive layer; and
shaping the second conductive layer to comprise a plurality of substantially pointed structures which interpenetrate through the first conductive layer and extend into the substrate.

13. The method of claim 12,
wherein the plurality of substantially pointed structures are formed through an annealing process.

14. The method of claim 12,
wherein the first conductive layer has a thickness which is less than 25% of a thickness of the second conductive layer.

15. The method of claim 12,
wherein the plurality substantially pointed structures are shaped to increase an adhesion between the first conductive layer and the substrate.

16. A method of forming a semiconductor structure, the method comprising:
providing a substrate;
forming a first conductive layer over a first side of the substrate;
forming a second conductive layer over the first conductive layer;
opening a plurality of perforations in the first conductive layer; and
creating a plurality of recesses in the substrate and arranging said recesses to be coaxial with the plurality of perforations.

17. The method of claim 16, further comprising:
shaping the second conductive layer to comprise a plurality of post-like structures which each extend through a perforation from said plurality and are coupled to a surface of a recess from said plurality.

18. The method of claim 16,
wherein the first conductive layer has a thickness which is less than 25% of a thickness of the second conductive layer.

19. The method of claim 16,
wherein the plurality of perforations and/or the plurality of recesses are formed through one or more semiconductor device fabrication techniques.

20. The method of claim 16,
wherein the plurality post-like structures are shaped to increase an adhesion between the first conductive layer and the substrate.
